(19) United States
(12) Patent Application Publication
(10) Pub. No.: US 2014/0151092 A1
(43) Pub. Date: Jun. 5, 2014

(54) PCB WITH VISIBLE CIRCUIT AND METHOD FOR MAKING AND USING PCB WITH VISIBLE CIRCUIT

(71) Applicants: Zhen Ding Technology Co., Ltd., Tayuan (TW); FuKui Precision Component (Shenzhen) Co., Ltd., Shenzhen (CN)

(72) Inventors: MING-JAAN HO, New Taipei (TW); XIAN-QIN HU, Shenzhen (CN)

(73) Assignees: Zhen Ding Technology Co., Ltd., Tayuan (TW); FuKui Precision Component (Shenzhen) Co., Ltd., Shenzhen (CN)

(21) Appl. No.: 14/085,654

(22) Filed: Nov. 20, 2013

(30) Foreign Application Priority Data
Nov. 30, 2012 (CN) 2012105026259

(51) Int. Cl. H05K 1/02; H05K 3/00

(52) U.S. Cl. CPC H05K 1/0274; H05K 3/00
USPC 174/251; 156/249

(57) ABSTRACT

A printed circuit board (PCB) with visible circuit includes a circuited substrate, a first and second release films, and a first and second optical clear adhesive (OCA) layers. The first and second release films are pressed onto and are adhered to two opposite surfaces of the circuited substrate via the first and second OCA layers respectively, and the first and second OCA layers are made of polymethyl methacrylate (PMMA).

### BACKGROUND

1. Technical Field

The present disclosure relates to printed circuit boards (PCBs) and, particularly to a PCB with visible circuit (i.e., clear/transparent PCB) and a method for making and using the PCB with visible circuit.

2. Description of Related Art

At present, PCBs are widely used. See Takahashi, A. Ooki, N. Nagai, A. Akahoshi, H. Mukoh, A. Wajima, M. Res. Lab, High density multilayer printed circuit board for HITAC M-880, IEEE Trans. on Components, Packaging, and Manufacturing Technology, 1992, 15(4): 1418-1425.

To meet certain requirements, a PCB with visible circuit is proposed, in which clear/transparent material is employed as a substrate and a cover film of the PCB with visible circuit, and, as such, circuits of the PCB with visible circuit sandwiched between the substrate and the cover film can be seen from outside. In use, the PCB with visible circuit is adhered to electronic modules using ultraviolet (UV) curable adhesive, which has less transparency. In addition, to ensure sufficient adhesive strength, the UV adhesive is often thick and thus further degrades a visibility of the PCB with visible circuit.

Therefore, it is desirable to provide a PCB with visible circuit and a method for making and using the PCB with visible circuit that can overcome the above-mentioned problems.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure.

FIG. 1 is a cross-sectional schematic view of a PCB with visible circuit, according to an embodiment.

FIG. 2 is a cross-sectional schematic view of a circuited substrate assembly, according to an embodiment.

FIG. 3 is a cross-sectional schematic view of a substrate of a circuited substrate, according to an embodiment.

### DETAILED DESCRIPTION

Embodiments of the present disclosure will be described with reference to the drawings.

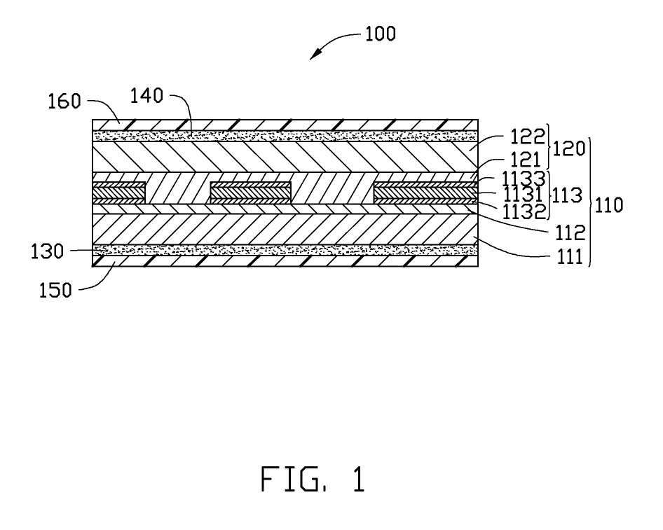

FIG. 1 shows a PCB with visible circuit 100, according to an embodiment. The circuited substrate 100 includes a circuited substrate 110, a first optical clear adhesive (OCA) layer 130, a second OCA layer 140, a first release film 150, and a second release film 160.

The circuited substrate 110 includes a clear substrate 111, a first adhesive layer 112, a circuit layer 113, and a cover film 120. The circuit layer 113 is adhered to the clear substrate 111 using the first adhesive layer 112. The cover film 120 is pressed onto and is adhered onto the circuit layer 113, opposite to the first adhesive layer 112.

The clear substrate 111 can be made of polyethylene terephthalate (PET) and has excellent optical properties (i.e., transparency) and weather resistance.

The first adhesive layer 112 can be made of OCA and has excellent optical properties (i.e., transparency).

The circuit layer 113 includes a conductive main layer 1131, a first black oxide layer 1132, and a second black oxide layer 1133. The first black oxide layer 1132 and the second black oxide layer 1133 are formed on two opposite surfaces of the conductive main layer 1131. In practice, the conductive main layer 1131 can be made of copper, and the first black oxide layer 1132 and the second black oxide layer 1133 are black oxide of the copper. In the illustrated embodiment, the first black oxide layer 1132 is adhered to the clear substrate 111 via the first adhesive layer 112.

The cover film 120 includes a second adhesive layer 121 and a dielectric layer 122. The dielectric layer 122 is adhered to the circuit layer 113 using the second adhesive layer 121. In practice, the second adhesive layer 121 fills any through structure formed in the circuit layer 112 and is directly adhered to the first adhesive layer 112 at where the circuit layer 112 has the through structure.

The second adhesive layer 121 can be made of OCA and has excellent optical properties (i.e., transparency).

The dielectric layer 122 can be made of PET and has excellent optical properties (i.e., transparency) and weather resistance.

The first release film 150 is adhered to the clear substrate 111, opposite to the first adhesive layer 112, using the first OCA layer 130.

The first OCA layer 130 can be made of polymethyl methacrylate (PMMA). A thickness of the first OCA layer 130 falls in a range from about 60 um to 90 um. A light transmittance of the first OCA layer 130 is greater than about 90%. A turbidity of the first OCA layer 130 is less than about 1%.

The first release film 150 can be made of PET and has excellent optical properties (i.e., transparency) and weather resistance. A thickness of the first release film 150 falls in a range from about 30 um to about 50 um.

The second release film 160 is adhered to the cover film 122, opposite to the second adhesive layer 121, using the second OCA layer 140.

The second OCA layer 140 can be made of PMMA. A thickness of the second OCA layer 140 falls in a range from about 60 um to 90 um. A light transmittance of the second OCA layer 140 is greater than about 90%. A turbidity of the second OCA layer 140 is less than about 1%.

The second release film 160 can be made of PET and has excellent optical properties (i.e., transparency) and weather resistance. A thickness of the second release film 160 falls in a range from about 30 um to about 50 um.

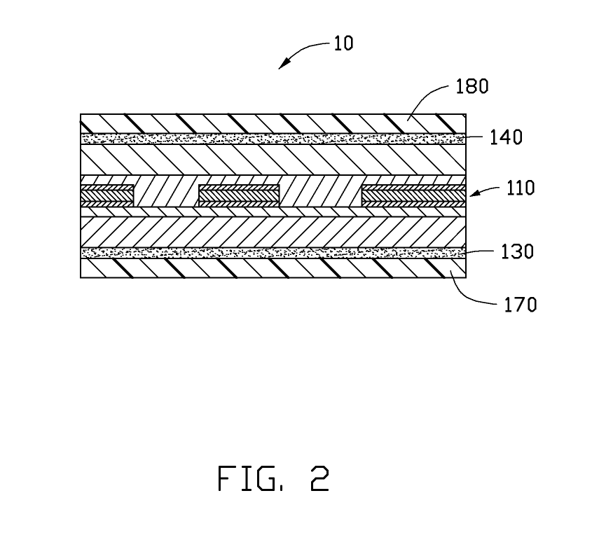

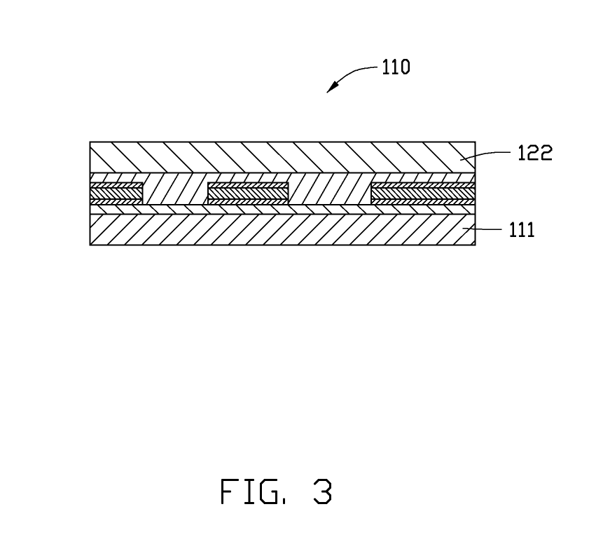

The first OCA layer 130 and the first adhesive film 150 can be integrated into an adhesive tape. The second OCA layer 140 and the second adhesive film 160 can also be integrated into an adhesive tape. Before use, the adhesive tapes are pasted to two opposite surfaces of the circuited substrate 110 (see FIG. 3), that is, the circuited substrate 110 is packaged by the first OCA layer 130, the second OCA layer 140, the first release film 150, and the second release film 160. As such, the first OCA layer 130 and the second OCA layer 140 are protected by the first release film 150 and the second release film 160. In use, the first release film 150 and the second release film 160 are removed to expose the first OCA layer 130 and the second OCA layer 140. In practice, the first OCA layer 130 and the second OCA layer 140 can be made of optical pressure sensitive adhesive and thus by pressing and then tearing off the first release film 150 and the second release film 160, the first OCA layer 130 and second OCA layer 140 entirely remain on the circuited substrate 110 for adhering purpose. Then, referring to FIG. 2, two electronic modules 170, 180, can be adhered to the circuited substrate 110 via the first OCA layer 130 and the second OCA layer 140.

By employing the first OCA layer 130 and the second OCA layer 140, which are made of PMMA, a transparency of the circuited substrate assembly 10 can be ensured.

It will be understood that the above particular embodiments are shown and described by way of illustration only. The principles and the features of the present disclosure may be employed in various and numerous embodiments thereof without departing from the scope of the disclosure. The above-described embodiments illustrate the possible scope of the disclosure but do not restrict the scope of the disclosure.

What is claimed is:

1. A printed circuit board (PCB) with visible circuit, comprising:
a circuited substrate; and
a first and second optical clear adhesive (OCA) layers deposited on two opposite surface of the circuited substrate
wherein the first and second OCA layers are made of polymethyl methacrylate (PMMA).

2. The PCB with visible circuit of claim 1, wherein the circuited substrate comprises a clear substrate, a first adhesive layer, a circuit layer, and a cover film, the circuit layer is adhered to the clear substrate using the first adhesive layer, and the cover film is pressed onto and adhered onto the circuit layer and is opposite to the first adhesive layer.

3. The PCB with visible circuit of claim 2, wherein the clear substrate is made of polyethylene terephthalate (PET).

4. The PCB with visible circuit of claim 2, wherein the first adhesive layer is made of OCA.

5. The PCB with visible circuit of claim 2, wherein the circuit layer comprises a conductive main layer, a first black oxide layer, and a second black oxide layer, and the first black oxide layer and the second black oxide layer are formed on two opposite surfaces of the conductive main layer.

6. The PCB with visible circuit of claim 2, wherein the cover film comprises a second adhesive layer and a dielectric layer, the dielectric layer is adhered to the circuit layer using the second adhesive layer.

7. The PCB with visible circuit of claim 6, wherein the second adhesive layer is made of OCA.

8. The PCB with visible circuit of claim 6, wherein the dielectric layer is made of PET.

9. The PCB with visible circuit of claim 1, wherein a thickness of the first OCA layer and the second OCA layer falls in a range from about 60 um to 90 um.

10. The PCB with visible circuit of claim 1, wherein light transmittance of the first OCA layer and the second OCA layer is greater than about 90%.

11. The PCB with visible circuit of claim 1, wherein a turbidity of the first OCA layer and the second OCA layer is less than about 1%.

12. The PCB with visible circuit of claim 1, further comprising a first release film and a second release film adhered to the opposite surface of the circuited substrate via the first OCA layer and second OCA layer respectively.

13. The PCB with visible circuit of claim 12, wherein the first release film and the second release are made of PET.

14. The PCB with visible circuit of claim 12, wherein a thickness of the first release film and the second release film falls in a range from about 30 um to about 50 um.

15. The PCB with visible circuit of claim 12, wherein the first OCA layer and the first adhesive film are integrated into an adhesive tape, the second OCA layer and the second adhesive film are integrated into an adhesive tape, and the OCA layer and the second OCA layer are made of optical pressure sensitive adhesive.

16. A method for making and using a PCB with visible circuit, the method comprising:
providing a circuited substrate;
providing two adhesive tapes, each of which comprises a release film and a layer of optical pressure sensitive adhesive applying on the release film;
pasting the two adhesive tapes onto two opposite surfaces of the circuited substrate using the layer of optical pressure sensitive adhesive which is mainly comprised of PMMA;
pressing the adhesive tapes and tearing off the release films to cause the layers of optical pressure sensitive adhesive entirely remaining on the circuited substrate;
providing two electronic modules; and
adhering the electronic modules to the circuited substrate via the layers of optical pressure sensitive adhesive.
